(19) United States
(12) Patent Application Publication
(10) Pub. No.: US 2004/0164645 A1
(43) Pub. Date: Aug. 26, 2004

(54) Surface acoustic wave device, method of manufacturing the same, and electronic apparatus

(75) Inventor: Masahiro Oshio, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/731,004

(22) Filed: Dec. 10, 2003

(30) Foreign Application Priority Data
Dec. 18, 2002 (JP) 2002-366713
Sep. 12, 2003 (JP) 2003-321797

(51) Int. Cl. H03H 9/25

(52) U.S. Cl. 310/313 B

(57) ABSTRACT

The present invention provides a surface acoustic wave device using a quasi-longitudinal leaky surface acoustic wave, which is capable of effectively suppressing spurious response and improving a Q value and a CI value. In particular, the present invention relates to a surface acoustic wave device including at least a quartz substrate and IDT electrodes arranged on the quartz substrate and exciting a quasi-longitudinal leaky surface acoustic wave, wherein a standardized electrode thickness t/λ, which standardizes a thickness t of the quartz substrate to an IDT wavelength λ, is set to be 1<t/λ<35, and the quartz substrate is cut out in the Euler angle range (0°, 100 to 150°, 0°).

### BACKGROUND OF THE INVENTION

1. Field of Invention

The present invention relates to a surface acoustic wave device, a method of manufacturing the same, and an electronic apparatus using the surface acoustic wave device. The present invention is preferably applied to a frequency selection filter provided in a mobile phone, and the like, an oscillator provided in a keyless entry system, and the like, and a resonator, and the like.

2. Description of Related Art

A surface acoustic wave device is a circuit that performs a signal process in which electric signals are converted into surface waves, and it is broadly used as a filter and a resonator. Usually, the electrodes composed of a conductive film called IDT electrodes are provided on a piezoelectric acoustic substrate (piezoelectric substrate) to perform the conversion and reverse conversion of electric signals into surface waves. The characteristics of the surface acoustic wave device depend on a propagation characteristic of the surface acoustic wave propagated on the piezoelectric substrate. Particularly, it is necessary to use a surface acoustic wave having a large phase velocity in order to cope with a high-frequency surface acoustic wave device.

A Rayleigh wave or a Leaky wave is mainly used as a surface acoustic wave used in the surface acoustic wave device. The Rayleigh wave is a surface wave that propagates the surface of the acoustic body and is propagated without radiating the energy into the piezoelectric substrate, i.e., without propagation loss in principle. A surface acoustic wave device using the Rayleigh wave includes a ST-cut quartz with 3150 [m/s] of phase velocity.

Three types of volume waves (bulk waves) of ‘slow transverse wave’, ‘fast transverse wave,’ and ‘longitudinal wave’ exist on the piezoelectric substrates, but the Rayleigh wave is propagated at a phase velocity much less than that of the ‘slow transverse wave’. The Leaky wave is a surface acoustic wave that propagates while radiating its energy in a direction of a depth of the acoustic body, and it is available at a special cutting angle and in a propagation direction. For example, an LST-cut quartz having a phase velocity of 3900 [m/s] is known. The Leaky wave propagates at a phase velocity between the ‘slow transverse wave’ and the ‘fast transverse wave’.

Further, by setting a propagation direction of the surface wave to 90° with respect to a propagation direction of the ST-cut quartz, along with the use of the quartz, it is known that the STW (Surface Transverse Wave) having a relatively large phase velocity can be used (for example, see ‘High Performance GHz Range Surface Transverse Wave Resonant Devices. Applications to Low Noise Microwave Oscillators and Communication System,’pp 132 to 137, 1995 Japan Society for the Promotion of Science, Cooperative Education Joint Research Support Business Report). According to this article, the phase velocity of the STW is 1.6 times as fast as a conventional ST-cut quartz. Recently, a quasi-longitudinal leaky surface acoustic wave, which propagates at a phase velocity between the ‘fast transverse wave’and the ‘longitudinal wave’ while radiating two transverse wave components into the piezoelectric substrate, has been subsequently found with the advance of the theory of Leaky wave. In the quasi-longitudinal leaky surface acoustic wave, most of the displacement in the surface of the substrate is composed of longitudinal wave components.

For examples, in lithium tetraborate, it should be noted that the quasi-longitudinal leaky surface acoustic wave having a large propagation velocity of 5000 [m/s] to 7500 [m/s] and a low propagation loss could be used (for example, see Japanese Unexamined Patent Application Publication No. 6-112763). Further, it has been reported that the quasi-longitudinal leaky surface acoustic wave can be used in the quartz substrate conventionally regarded as an improper material for a high-frequency surface acoustic wave device (for example, ‘study of Propagation of Quasi-longitudinal Leaky Surface Acoustic Wave Propagating on Y-Rotated Cut Quartz Substrates,’ pp 321-324, 1999 IEEE ULTRASONICS SYMPOSIUM). According to the 1999 IEEE article in the biaxial rotation of Euler angle (0°, 155.25°, 42°), when the quasi-longitudinal leaky surface acoustic wave is used, it has been found that a delay time temperature coefficient TCD is 0.508 [ppm/° C.].

Further, it has been found by an analysis using a Finite Element Method that when the quasi-longitudinal leaky surface acoustic wave is used, a frequency-temperature behavior follows to 3^{rd} order function curve in uniaxial rotated cut plane (for example, see ANALYSIS OF VELOCITY PSEUDO-SURFACEACOUSTIC WAVES (HVPSAW) IN QUARTZ PERIODIC STRUCTURES WITH ELECTRODEFINGERS, '2000 FCS, Kansas Mo. USA Jun. 7-9, 2000). As described above, since the quasi-longitudinal leaky surface acoustic wave has a high phase velocity, a high-frequency surface acoustic wave device can be easily realized, which is not achieved by a Rayleigh wave or a Leaky wave. In addition, it is possible to easily manufacture a surface acoustic wave device by preventing the yield of manufacture from being decreased by the miniaturization of the IDT electrode.

### SUMMARY OF THE INVENTION

However, when the quasi-longitudinal leaky surface acoustic wave is used and quartz, which is an inexpensive and stable material, is used as a substrate material, its impropriety has been confirmed wherein spurious response occurs at some strength. When the surface acoustic wave device is used in a resonator and the spurious response occurs in the vicinity of main resonance, the spurious response causes a CI (Crystal Impedance) value or a Q value to be deteriorated. Furthermore, when an oscillating circuit is constructed, the spurious can cause a delinquency of an abnormal oscillation or frequency jump.

Accordingly, an object of the present invention is to provide a surface acoustic wave device using a quasi-longitudinal leaky surface acoustic wave, which can effectively suppress the spurious response and improve a Q value or a CI value, and a method of manufacturing the same. Further, another object of the present invention is to provide an electronic apparatus including the surface acoustic wave device using the quasi-longitudinal leaky surface acoustic wave, in which a filter or a resonator capable of effectively suppressing spurious response and of improving a Q value or a CI value is used.

Since it is required to suppress the spurious response in order to solve the problems and obtain the objects of the present invention, research has been conducted suppressing it. As a result of the research, the spurious response is detected at a frequency that depends on the thickness of the quartz substrate, and it is found that the Q value or the CI value changes depending on the thickness of the quartz substrate. The present invention is completed based on the aforementioned knowledge, and its construction is as follows.

In other words, a first invention relates to a surface acoustic wave device, which includes a quartz substrate and IDT electrodes arranged on the quartz substrate and exciting a quasi-longitudinal leaky surface acoustic wave. A standardized substrate thickness t/λ, which standardizes a thickness t of the quartz substrate to an IDT wavelength λ, is set to be 1<t/λ<35. Herein, when the standardized substrate thickness t/λ, is in the range of 25<t/λ<35, the quartz substrate is easily manufactured since the thickness t of the quartz substrate is not so very thin. However, when the quartz substrate is used as a resonator, a sufficient figure of merit cannot be obtained (see FIG. 5), and thus it is not sufficient as an electric characteristic.

Further, if the standardized substrate thickness t/λ is in the range of 10<t/λ<25, the quartz substrate has a relatively thin thickness, but the manufacture is relatively easy. In addition, a sufficient figure of merit is obtained, and thus the electrical characteristic becomes very excellent (see FIG. 5). Moreover, if the standardized substrate thickness t/λ is in the range of 1<t/λ<10, the thickness t of the quartz substrate is very thin, and thus it is difficult to manufacture a quartz substrate. However, a very sufficient figure of merit is obtained, and thus its electric characteristic becomes excellent.

In this way, according to the first invention, it is possible to provide a surface acoustic wave device, in which the quasi-longitudinal leaky surface acoustic wave exciting the quartz substrate device is used and the spurious response is suppressed. Also, the Q value becomes large, and thus a surface acoustic wave element capable of operating within the range of inductive reactance is realized. Thus, when the surface acoustic wave element is used in an oscillator, it is possible to provide a higher stable oscillator. Further, if an oscillating circuit is constructed, it is possible to prevent defect such as abnormal oscillation or oscillating frequency jump.

In this way, it is possible to use the quasi-longitudinal leaky surface acoustic wave having a high phase velocity by adjusting the thickness of the quartz substrate, and thus the width of electrode and the gap between the electrodes become larger as compared when a Rayleigh wave or a leaky surface acoustic wave is used. As a result, it is possible to improve the yield of manufacture. According to the invention, in the surface acoustic wave device of the first invention, the quartz substrate is cut out in the Euler angle range (0°, 100 to 150°, 0°).

Herein, when the quartz substrate is cut out in the Euler angle range (0°, 100 to 150°, 0°) as described the above, it is possible to generate the quasi-longitudinal wave leaky surface acoustic wave. Further, if the Euler angle is in the range of (0°, 125 to 150°, 0°), it is possible to lower the loss accompanied with the propagation of the quasi-longitudinal leaky surface acoustic wave, thereby improving the Q value. As described above, according to the second invention, since it is possible to use the quartz substrate of uniaxial rotated cut plane to generate the quasi-longitudinal leaky surface acoustic wave, the manufacture management is easy, and thus it is possible to provide a low-cost and stable surface acoustic wave device.

According to the present invention, in the surface acoustic wave device of the first or second invention, in the quartz substrate, a reinforcement portion is provided on at least one of an IDT electrode-forming surface and an opposite surface thereto in a region except for the region where the IDT electrode is formed. In this way, because the mechanical strength of the quartz substrate becomes larger as compared with a case where the reinforcement portion is not provided, it is possible to prevent the crack and breakage of the quartz substrate in the manufacturing process and thus to improve the yield.

The invention can also relate to an electronic apparatus including a surface acoustic wave device as a filter or a resonator. The surface acoustic wave device is composed of the surface acoustic wave device according to any one of the first to third inventions. Thus, it is possible to provide an electronic apparatus using a filter or a resonator, in which spurious response is suppressed and the quasi-longitudinal leaky surface acoustic wave exciting the quartz substrate is used.

The invention can also include a first step of adjusting the thickness of a quartz substrate; a second step of forming IDT electrodes for exciting a quasi-longitudinal leaky surface acoustic wave on the thickness-adjusted quartz substrate to obtain a surface acoustic wave element, and a third step of fixing the surface acoustic wave element on a predetermined package. In the first step, the thickness of the quartz substrate is adjusted such that a substrate standardized thickness t/λ, which standardizes a thickness t of the quartz substrate to an IDT wave λ, satisfies 1<t/λ<35.

According the above method, because the thickness of the quartz substrate is adjusted before the IDT electrodes are formed, it is possible to manufacture a surface acoustic wave device capable of suppressing the spurious response and of improving the Q value or the CI value without invading the IDT electrode pattern.

The present invention can include a first step of forming IDT electrodes for exciting a quasi-longitudinal leaky surface acoustic wave on the quartz substrate to obtain a surface acoustic wave element, a second step of adjusting the thickness of the quartz substrate by shaving a surface of the quartz substrate opposite to an IDT electrode-forming surface, and a third step of fixing the surface acoustic wave element on a predetermined package, wherein in the second step, the thickness of the quartz substrate is adjusted such that the standardized substrate thickness t/λ, which standardizes a thickness t of the quartz substrate to an IDT wave λ, satisfies 1<t/λ<35.

According to the above method, since the IDT electrodes are formed before the thickness of the quartz substrate is adjusted, it is possible to prevent breakage in the process of forming the IDT electrodes and thus to improve the yield of a product.

In a method of manufacturing the surface acoustic wave device according to the present invention, the inventor can further include a frequency-adjusting step of adjusting the frequency of the surface acoustic wave element after the third step, wherein in the frequency-adjusting step, the thickness of the quartz substrate is adjusted at a surface opposite to the IDT electrode-forming surface.

In the method of manufacturing the surface acoustic wave device according to the above invention, the present invention can relate to frequency adjustment, and the frequency adjustment is implemented by shaving a surface of the quartz substrate opposite to the IDT electrode-forming surface using a dry etching method. According to the above invention, it can be possible to adjust a frequency without invading the electrode pattern formed on the electrode-forming surface of the quartz substrate at all. Thus, it is possible to decrease a change in center frequency with the lapse of time and thus to realize a stable surface acoustic wave device for a long term.

Further, as compared with a case where the frequency adjustment is performed by etching the electrode-forming surface, it is possible to adjust frequency with high precision since the frequency fluctuation according to the amount of etching is small. According to the invention, in the method of manufacturing the surface acoustic wave device according to the above invention, a preliminary frequency adjustment is performed by shaving at least one of the IDT electrode-forming surface of the quartz substrate and the surface of the IDT electrode prior to the aforementioned frequency adjustment.

According to the present invention, when substantial adjustment of a frequency into a large width is necessary, first of all, the frequency is roughly and preliminary adjusted by wet-etching the electrode-forming surface, and then it is possible to perform a precise frequency adjustment by etching the electrode-forming surface and an opposite surface thereto. For this reason, it is possible to adjust the frequency in a short time. Even in this case, since it is not necessary to etch the electrode-forming surface using plasma, etc., it is possible to prevent the frequency fluctuation due to the remaining aluminum as generated in the prior art and thus to provide a long-lived and stable surface acoustic wave device.

As described the above, according to the present invention, in the surface acoustic wave device using the quasi-longitudinal leaky surface acoustic wave, it is possible to provide a surface acoustic wave device capable of effectively suppressing spurious response and of improving the Q value or the CI value. Further, according to the present invention, it is possible to realize a long-lived and stable surface acoustic wave device, in which the frequency is adjusted with high precision and a center frequency is hardly changed after adjustment with the lapse of time.

Further, according to the present invention, in an electronic apparatus including the surface acoustic wave device using the quasi-longitudinal leaky surface acoustic wave, it is possible to provide an electronic apparatus using a filter or a resonator, which is capable of effectively suppressing spurious response and improving the Q value or the CI value.

### BRIEF DESCRIPTION OF THE DRAWINGS

The invention will be described with reference to the accompanying drawings, wherein like numerals reference like elements, and wherein:

FIG. 1 shows the schematic construction of a surface acoustic wave device according to the first embodiment of the present invention, wherein (a) is a perspective view, and (b) is a cross-sectional view taken along the line A-A of (a);

FIG. 2 is a view showing the frequency to impedance characteristic of a resonator using a quasi-longitudinal leaky surface acoustic wave when a standardized substrate thickness t/λ is 37.5;

FIG. 3 is a view showing the frequency to impedance characteristic of the resonator when the standardized substrate thickness t/λ is 8;

FIG. 4 is a view showing an example of the measurement result of variation in frequency of the main resonant frequency and the frequency of the spurious response with respect to the standardized substrate thickness t/λ;

FIG. 5 is a view showing the variation of the Figure of merit M with respect to the standardized substrate thickness t/λ of the resonator;

FIG. 6 is a view showing a general equivalent circuit of the resonator;

FIG. 7 is a cross-sectional view showing the construction of a modification of the surface acoustic wave device according to the embodiment of the present invention;

FIG. 8 is a flow chart explaining a first embodiment of a method of manufacturing the surface acoustic wave device according to the present invention;

FIG. 9 is a flow chart explaining a second embodiment of the method of manufacturing the surface acoustic wave device according to the present invention;

FIG. 10 is a view showing an example of the measurement result of the amount of frequency variation with respect to the etching amount of the rear surface of a quartz substrate;

FIG. 11 is a view showing an example of the measurement result of the amount of frequency variation with respect to the etching amount of each of the surface and the rear surface of the quartz substrate;

FIG. 12 is a flow chart explaining the procedure of a second method of adjusting the frequency shown in FIG. 8 or FIG. 9;

FIG. 13 is a flow chart explaining the procedure of a first method of adjusting the frequency; and

FIG. 14 is a view showing the variation of propagation loss in the Euler angle range (0°, 100 to 150°, 0°).

### DETAILED DESCRIPTION OF PREFERRED EMBODIMENTS

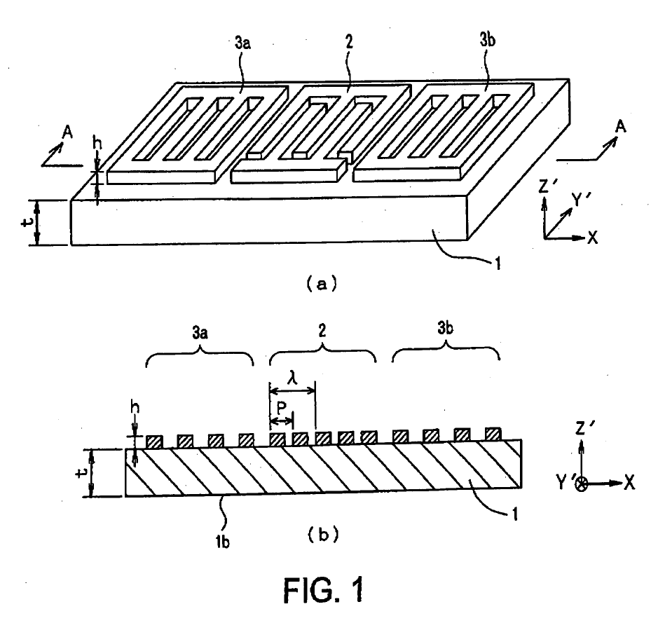

Hereinafter, the embodiments of the present invention will be described with reference to the accompanying drawings. FIG. 1(a) is a perspective view illustrating the schematic construction of a surface acoustic wave device according to an embodiment of the present invention, and FIG. 1(b) is a cross-section view taken along the line A-A of FIG. 1(a). As shown in FIG. 1, a surface acoustic wave device according to the present embodiment comprises a quartz substrate 1, an IDT electrode 2 formed on the main surface of the quartz substrate 1, and reflector electrodes 3a and 3b.

In FIG. 1, t is the thickness of the quartz substrate 1, p is the pitch of the IDT electrode 2, λ is an IDT wavelength, and h is the thickness of the IDT electrode 2. The quartz substrate 1 is cut in the Euler angle range (0°, 100 to 150°, 0°). Also, the thickness t of the quartz substrate 1 is adjusted to sufficiently suppress spurious response. For example, when an oscillating circuit is constructed, the thickness is set to a value by which no abnormal oscillation or frequency jump (frequency shift) occurs. the above will be described in greater detail below.

The IDT electrode 2 excites a quasi-longitudinal leaky surface acoustic wave on the quartz substrate 1 in parallel with a positive X-axis, and for example, the standardized electrode thickness h/λ is set to be 0.02 or more. Herein, the standardized electrode thickness h/λ is to standardize the thickness h of the IDT electrode 2 to the IDT wavelength λ. The reflector electrodes 3a and 3b reflect and resonate the quasi-longitudinal leaky surface acoustic wave that generates on the surface of the quartz substrate 1.

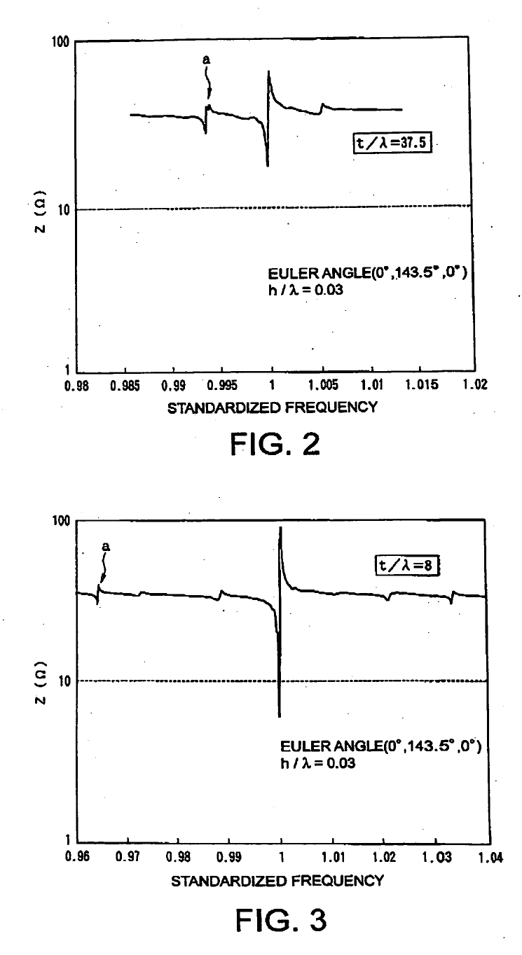

FIG. 2 is a view showing a frequency to impedance characteristic of the resonator using the quasi-longitudinal leaky surface acoustic wave when the standardized electrode thickness t/λ, which standardizes the thickness t of the quartz substrate 1 to the IDT wavelength λ, is set to 37.5. In FIG. 2, the Euler angle is (0°, 143.5°, 0°), and the standardized electrode thickness h/λ is 0.03. Also, a frequency f is a standardized frequency f/f0 standardizing a serial resonant frequency f0, and the standardized main oscillating frequency f/f0 is 1.

FIG. 3 is a view showing a frequency to impedance characteristic of a resonator when the standardized substrate thickness t/λ is set to 8. In FIG. 3, the Euler angle is (0°, 143.5°, 0°), and the standardized electrode thickness h/λ is 0.03. Like a conventional case, FIG. 2 shows a case where no adjustment is performed on the thickness of the quartz substrate. In this case, spurious response a, which has a sufficient CI value to generate defect, such as abnormal oscillation or frequency jump very close to the main resonant frequency, is detected, and thus it has no practical use.

On the contrary, FIG. 3 shows a case where the thickness of the quartz substrate is adjusted and represents the same spurious response as the spurious response a detected in FIG. 2 as a. As described above, if the thickness of the quartz substrate is adjusted, it can be known that the frequency difference with the main resonance becomes large, and thus spurious response a is suppressed. Also, in FIG. 3, another spurious response is generated near the main resonant frequency, but CI value is large as compared with the above-mentioned spurious response a, and thus it is not at a problematic level.

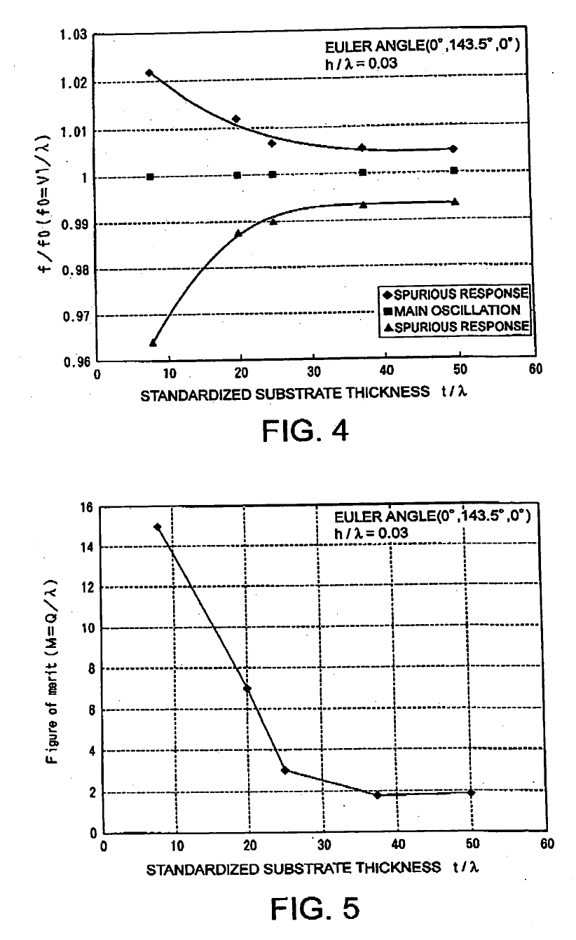

FIG. 4 shows the result of measuring the variation of the main resonant frequency and the frequency of the spurious response with respect to the standardized substrate thickness t/λ. In FIG. 4, the Euler angle is (0°, 143.5°, 0°), and the standardized electrode thickness h/λ is 0.03. Referring to FIG. 4, if the standardized substrate thickness t/λ is small, the frequency difference between the main resonant frequency and the frequency of the spurious response becomes large according to such a situation, and it means that spurious response is suppressed.

The cause of spurious response is a high-order mode bulk wave that is generated by the oscillation of the whole quartz substrate, and the resonant frequency is a standing wave that is determined by the thickness of the quartz substrate. Therefore, the resonant frequency difference between standing waves different in order becomes large by making the quartz substrate thin. Specifically, the frequency difference between the frequency of the spurious response and the main resonant frequency becomes large, and thus it is possible to suppress spurious response. As such, by adjusting the thickness of the quartz substrate, which was not included in the design conditions of a conventional surface acoustic wave device, it is possible to effectively suppress spurious response, which is unfit in a case where the quasi-longitudinal wave leaky surface acoustic wave having a large phase velocity is used, using the quartz substrate. Furthermore, it is possible to prevent defect, such as abnormal oscillation or frequency jump when an oscillating circuit is constructed.

FIG. 5 is a view showing variation in Figure of merit M with respect to the standardized substrate thickness t/λ of a resonator. In FIG. 5, the Euler angle is (0°, 143.5°, 0°), and the standardized electrode thickness h/λ, is 0.03. The Figure of merit M is used as the valuation reference when it is used in an oscillating circuit, which is operated by inductive reactance, and divides resonant quality factor Q into capacitance ratio γ. It represents the strength of oscillation when looking a mechanical oscillator from the electric terminal. As the Figure of merit M becomes large, it is possible to provide an oscillator having excellent frequency stability.

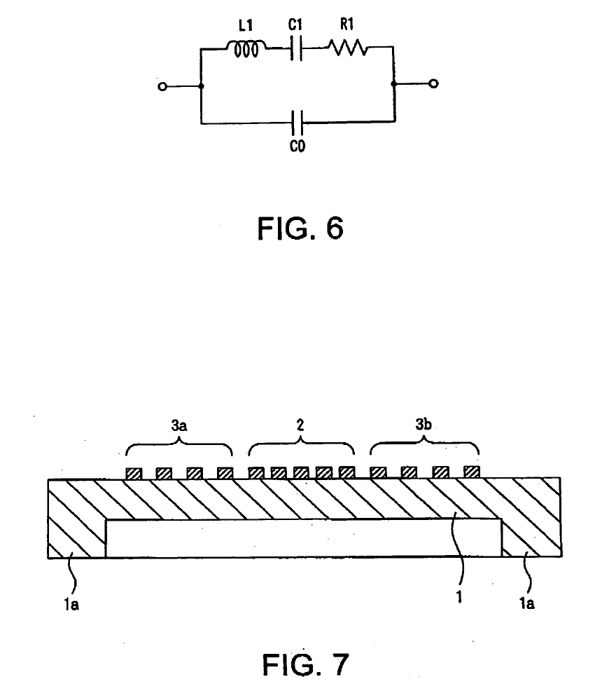

Also, when a general equivalent circuit of the resonator shown in FIG. 6 is used, capacitance ratio γ is defined as a ratio of parallel capacitance C0 and serial capacitance C1 and is indicated by γ=C0/C1. Furthermore, the resonance quality factor Q is represented by Q=ω0×(L1/R1) using a serial resonant angular frequency ω0, an equivalent serial inductance L1, and an equivalent serial resistance R1. As shown in FIG. 5, since the standardized substrate thickness t/λ is 35 or less, the Figure of merit M becomes more than 2, and reactance is a positive value, i.e., an inductive frequency is generated. Thus, it is possible to provide an oscillator having excellent frequency stability required for an oscillator.

This means that if the standardized substrate thickness t/λ is more than 35, the Q value of the main resonance decreases due to spurious response, and the CI value becomes large, on the contrary, if the standardized substrate thickness t/λ is 35 or less, spurious response is suppressed and the Q value and CI value of the main resonance is improved. As describe above, in the surface acoustic wave device according to the present embodiment, the standardized substrate thickness t/λ is preferably 35 or less in view of the electric characteristic. Furthermore, if it is 1 or more, it is possible to include most of the energy of the surface acoustic wave without decreasing the manufacturing yield. Therefore, the range of the standardized substrate thickness t/λ satisfies the following Equation.

1<t/λ<35 (1)

wherein, if the standardized substrate thickness t/λ is in the range of 25<t/λ<35, it is possible to easily manufacture the quartz substrate since the thickness t of the quartz substrate is not so thin. Furthermore, a sufficient Figure of merit M cannot be obtained, and thus it is inadequate for an electric characteristic (see FIG. 5). Moreover, when the standardized substrate thickness t/λ is in the range of 10<t/λ<25, the thickness of the quartz substrate is relatively thin, and it is relatively easy to manufacture the quartz substrate. In addition, it is possible to obtain a sufficient Figure of merit M and an excellent electric characteristic.

This is because when the standardized substrate thickness t/λ is in the range of 10<t/λ<25 as compared with a case where the standardized substrate thickness t/λ is in the range of 25<t/λ<35, the value of Figure of merit M suddenly increases (see FIG. 5). Further, when the standardized substrate thickness t/λ is in the range of 1<t/λ<10, the thickness t of the quartz substrate is very thin, and thus it is difficult to manufacture the quartz substrate. However, a sufficient Figure of merit M can be obtained, and thus the electric characteristic is very excellent.

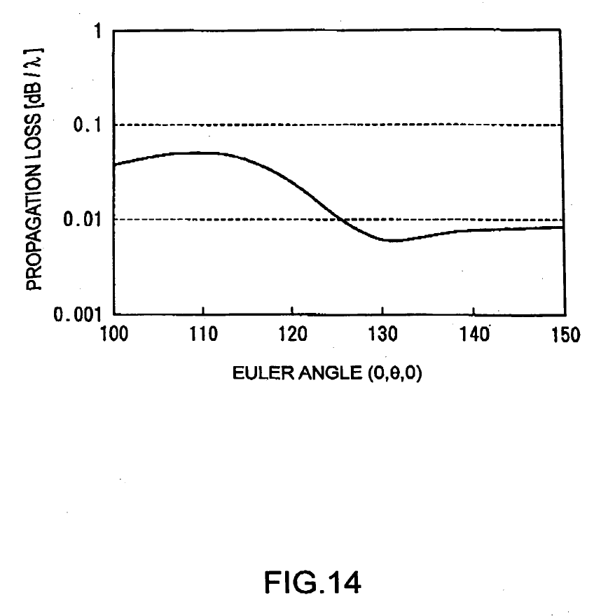

FIG. 14 is a view illustrating the variation of propagation loss in Euler angle (0°, 100 to 150°, 0°). As shown in FIG. 14, propagation loss in the Euler angle (0°, 125 to 150°, 0°) is 10−² [dB/λ] or less, i.e., the quasi-longitudinal leaky surface acoustic wave can propagate with hardly radiating energy into the substrate. Because the Q value is in an inverse relation to the energy loss, the Q value or the Figure of merit M becomes larger when the quartz substrate, which is cut out in the above-described range, is used. Thus, it is possible to provide a high efficient filer or resonator.

As described above, in the surface acoustic wave device according to the present embodiment of the present invention, although the quasi-longitudinal wave leaky surface acoustic wave exciting the quartz substrate is used, it is possible to provide a surface acoustic wave device capable of suppressing spurious response. Also, the Q value becomes large, and a surface acoustic wave element operable in the range of inductive reactance is realized. Therefore, it is possible to provide a high stable oscillator when the surface acoustic wave element is used for an oscillator. Further, when an oscillating circuit is constructed, it is possible to prevent defect such as abnormal oscillation or oscillating frequency jump (oscillating frequency shift).

In addition, as described in the present embodiment, it is possible to use the quasi-longitudinal leaky surface acoustic wave having a high phase velocity by adjusting the thickness of the quartz substrate. Thus, as compared with a case where a Rayleigh wave or a leaky surface acoustic wave is used, the width of the electrode and a gap between the electrodes become large, thereby improving the manufacture yield. Further, even if the standardized electrode thickness t/λ is restricted, it is possible to have a margin to the film thickness h of the IDT electrode as compared with a case where the Rayleigh wave or Leaky wave is used. Moreover, it is possible to prevent reduction in the Q value by suppressing an increase of electric resistance loss. Also, even in a bonding method using wire bonding, it is possible to prevent the exfoliation of electrode in wire bonding and thus to easily cope with high frequency operation.

Next, a modification of the surface acoustic wave device according to the present embodiment of the present invention will be described with reference to FIG. 7. In the modification, a reinforcement portion 1a is provided along the circumference of the rear surface of the quartz substrate 1. That is, the reinforcement portion 1a is provided on the rear surface of the quartz substrate 1, which is a region except for the region opposite to the IDT electrode 2 and the reflector electrodes 3a and 3b arranged on the surface thereof.

Herein, since the construction of the aforementioned modification is the same as that of the embodiment shown in FIG. 1 except for the reinforcement portion 1a, description thereof will be omitted. Also, in the above-mentioned modification, the reinforcement portion 1a is provided along the circumference of the rear surface of the quartz substrate 1. However, the reinforcement portion 1a may be provided along the circumference of the front surface of the quartz substrate 1, or the reinforcement portion 1a may be provided along the circumference of the front surface and the rear surface of the quartz substrate 1.

As described above, according to the modification, since the reinforcement portion is provided, the mechanical strength of the quartz substrate becomes large as compared with a case where no reinforcement portion is provided. Thus, crack and breakage in the process is prevented, and thus yield can be improved.

Next, an embodiment of an electronic apparatus according to the present invention will be described. The electronic apparatus according to the embodiment includes, for example, a mobile phone or a keyless entry system, and so on. In case of a mobile phone, the surface acoustic wave device shown in FIG. 1 or FIG. 7 is used as a frequency selection filter of the mobile phone. Furthermore, in case of the keyless entry system, the surface acoustic wave device is used as a resonator of an oscillator of the keyless entry system.

That is, the electronic apparatus according to the present embodiment includes the surface acoustic wave device shown in FIG. 1 or FIG. 7 as a filter or an oscillator. According to the electronic apparatus constructed as described above, it is possible to provide an electronic apparatus using a filter or an oscillator, in which spurious response is suppressed, while using the quasi-longitudinal leaky surface acoustic wave for exciting the quartz substrate.

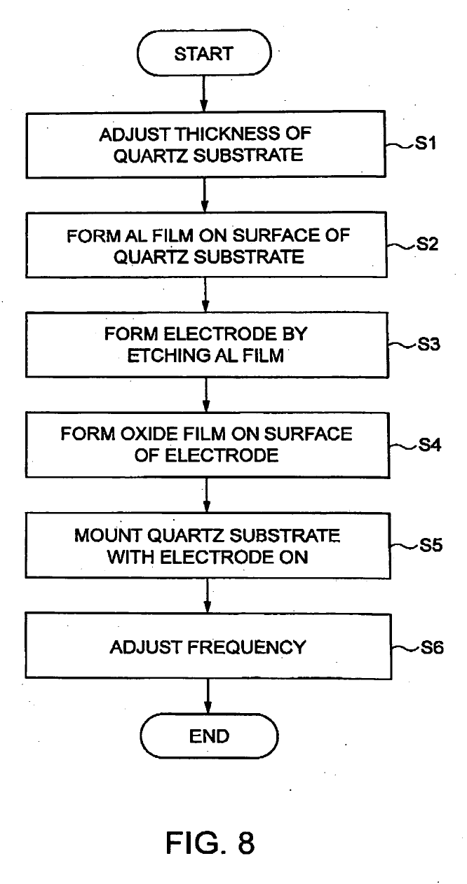

Next, a first embodiment of a method of manufacturing the surface acoustic wave device according to the present invention will be described with reference to FIG. 8. In the first embodiment, a method of manufacturing the surface acoustic wave device shown in FIG. 1 will be described. First, a thickness t of the quartz substrate 1 is adjusted (step S1). The adjustment of the thickness t of the quartz substrate 1 is performed by uniformly shaving off the surface or the rear surface of the quartz substrate 1 by etching or polishing. At this time, the final thickness t of the quartz substrate 1 satisfies the above-described Equation 1.

In the next step S2, for example, an aluminum (Al) film is formed on the surface of the quartz substrate 1 subjected to the thickness adjustment. In the next step S3, the aluminum film is shaved off by etching or polishing, and then reflector electrodes 3a and 3b and an IDT electrode 2 for exciting the quasi-longitudinal leaky surface acoustic wave are formed respectively to obtain the desired surface acoustic wave element. In the next step S4, an oxide film is formed on the surfaces of the IDT electrode 2 and the reflector electrodes 3a and 3b. In the next step S5, the surface acoustic wave element is mounted on a package. In the final step S6, the frequency adjustment of the surface acoustic wave element mounted on the package is performed.

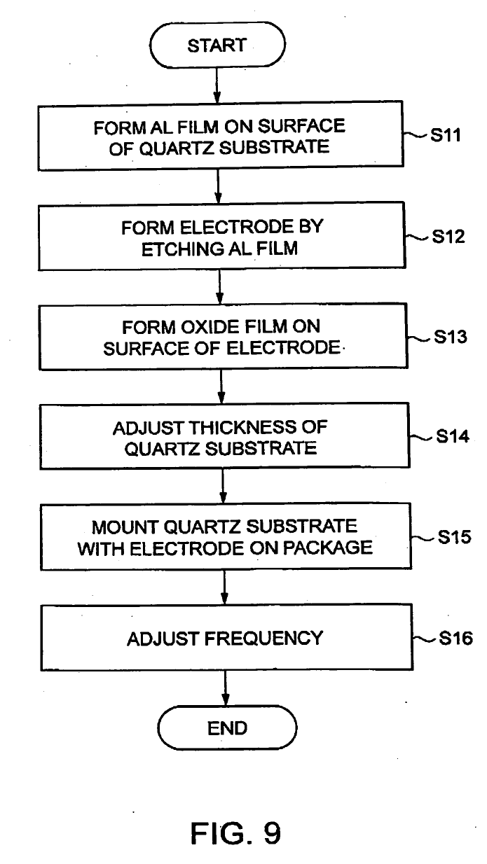

As described above, in the first embodiment according to the manufacturing method, since the thickness of the quartz substrate is adjusted before the IDT electrode and the like are formed, it is possible to manufacture a surface acoustic wave device capable of suppressing spurious response and of improving the Q value or the CI value. Next, a second embodiment of the method of manufacturing the surface acoustic wave device according to the present invention will be described with reference to FIG. 9.

In the second embodiment related to the manufacturing method, a method of manufacturing the surface acoustic wave device shown in FIG. 1 will be described. First, a quartz substrate 1 having the desired thickness is prepared, and for example, an aluminum (Al) film is formed on the surface of the quartz substrate 1 (step S11). In the next step S12, the aluminum film is shaved off by etching or polishing, and then reflector electrodes 3a and 3b and an IDT electrode 2 for exciting the quasi-longitudinal leaky surface acoustic wave are formed respectively to obtain the desired surface acoustic wave element.

In the next step S13, an oxide film is formed on the surfaces of the IDT electrode 2 and the reflector electrodes 3a and 3b. In the next step S14, the thickness t of the quartz substrate 1 is adjusted. The adjustment of the thickness t of the quartz substrate 1 is performed by uniformly shaving off the rear surface of the quartz substrate 1 by etching or polishing. At this time, the final thickness t of the quartz substrate 1 satisfies the above-described Equation 1.

In the next step S15, the surface acoustic wave element is mounted (fixed) on a package. In the final step S16, the frequency adjustment of the surface acoustic wave element mounted on the package is performed. As described above, according to the second embodiment related to the manufacturing method, since the IDT electrode, etc. is formed before the thickness of the quartz substrate is adjusted, it is possible to prevent breakage in the step of forming the IDT electrode, etc., and thus to improve the yield of the product.

However, in the first embodiment of a method of manufacturing the surface acoustic wave device according to the present invention, as shown in FIG. 8, the frequency adjustment of the surface acoustic wave element is performed in the step S6, and thus in the second embodiment of a method of manufacturing the surface acoustic wave device according to the present invention, as shown in FIG. 9, the frequency adjustment is performed in the step S16. Therefore, the specific examples of a method of adjusting the frequency of the surface acoustic wave device will now be described.

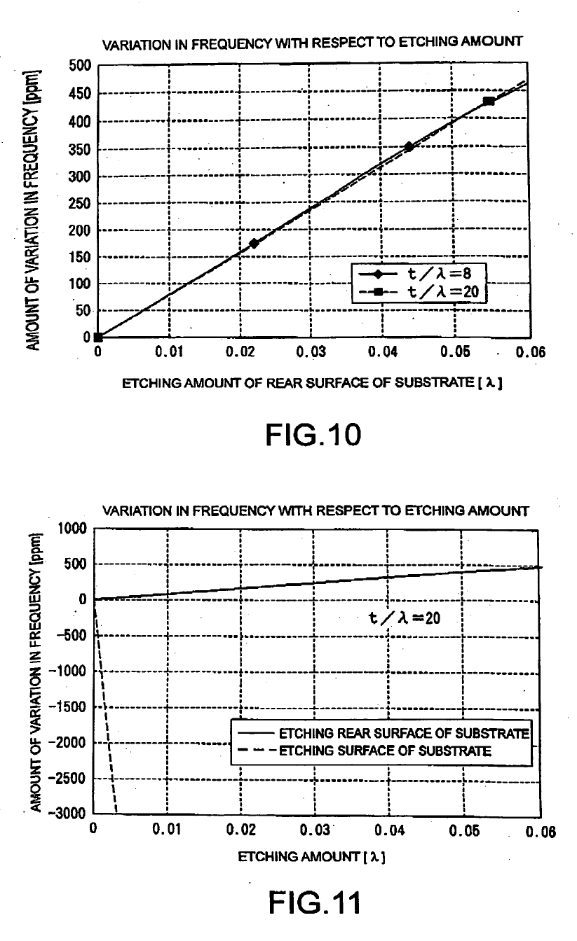

First, before specifically describing a method of adjusting the frequency of the surface acoustic wave element, the principle of a method of adjusting the frequency will be described with reference to FIG. 10 and FIG. 11. FIG. 10 is a view showing one example of the measured results of the amount of frequency variation to the amount of the etching of the surface (the rear side) opposite to the electrode-forming surface (the front side) of the quartz substrate. The measured results describe a case where the standardized substrate thicknesses t/λ standardizing the thickness t of the quartz substrate to an IDT wavelength λ are 8 and 20. Also, the Euler angle is (0°, 143.5°, 0°) and the standardized electrode thickness h/λ is 0.03. Herein, the standardized electrode thickness h/λ is to standardize the thickness h of the IDT electrode 2 to the IDT wavelength λ.

FIG. 11 is a view showing an example of the measured results of the amount of frequency variation to the amount of the etching of each of the surface and the rear surface of the quartz substrate. The measured results describe a case where the standardized substrate thickness t/λ is 20, the Euler angle is (0°, 143.5°, 0°), and the standardized electrode thickness h/λ is 0.03. Referring to FIG. 10, a surface (rear surface) opposite to the electrode-forming surface of the quartz substrate is etched to make the thickness of the quartz substrate thin, and then the center frequency (resonant frequency) increases, thereby adjusting the frequency of the surface acoustic wave device.

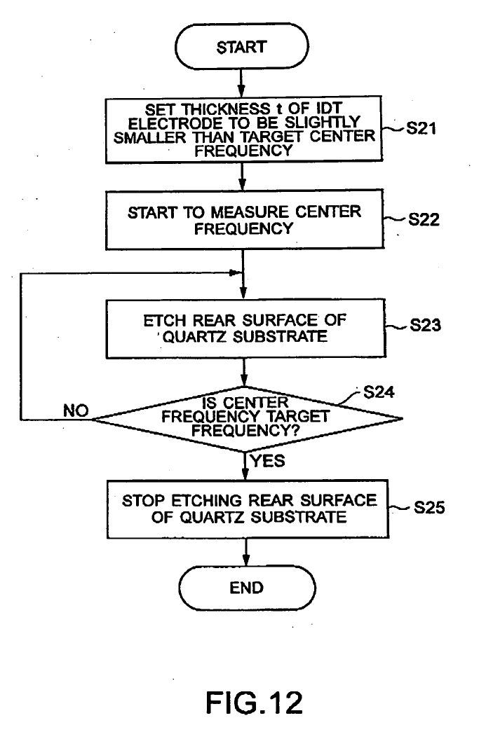

Also, according to FIG. 11, as compared with a case where etching of the surface of the quartz substrate is performed, a case where etching of its rear surface is performed has a small amount of frequency variation to the amount of the etching. Furthermore, in such a case, it is suitable for the adjustment of an accurate frequency, and more particularly, it is suitable for the frequency adjustment of the surface acoustic wave device having a high frequency and a short IDT wavelength. Therefore, the above-described frequency adjustment method enables the accurate frequency adjustment by etching a surface opposite to the electrode-forming surface of the quartz substrate in view of the above facts. Also, as compared with the amount of adjustment of the thickness of the substrate to suppress the aforementioned spurious response, since the amount of adjustment of the thickness of the substrate to adjust the above frequency is very small, no problem such as spurious response occurs. Next, the first method of adjusting the frequency of the surface acoustic wave device will be described with reference to FIG. 12.

In this case, for example, the thickness h of the IDT electrode 2 formed on the quartz substrate 1 is made slightly more thicker than a target thickness, and the center frequency is set to be lower than the target value (step S21). Next, the measurement of the center frequency (input-output measurement) starts by applying a voltage to the IDT electrode 2 (step S22). At this time, the measured center frequency is slightly lower than the target value. Then, the etching of the rear surface 1b of the quartz substrate 1 is performed while confirming the measured frequency (step S23). Herein, dry etching is very suitable for the above-described etching.

Then, the center frequency rises gradually and approaches the target value by the etching. Then, the etching continues until the center frequency reaches the target value (steps S23 and S24), and then the etching stops when it becomes the target value (step S25). According to the aforementioned method of adjusting the frequency, the center frequency can be accurately adjusted to the target value.

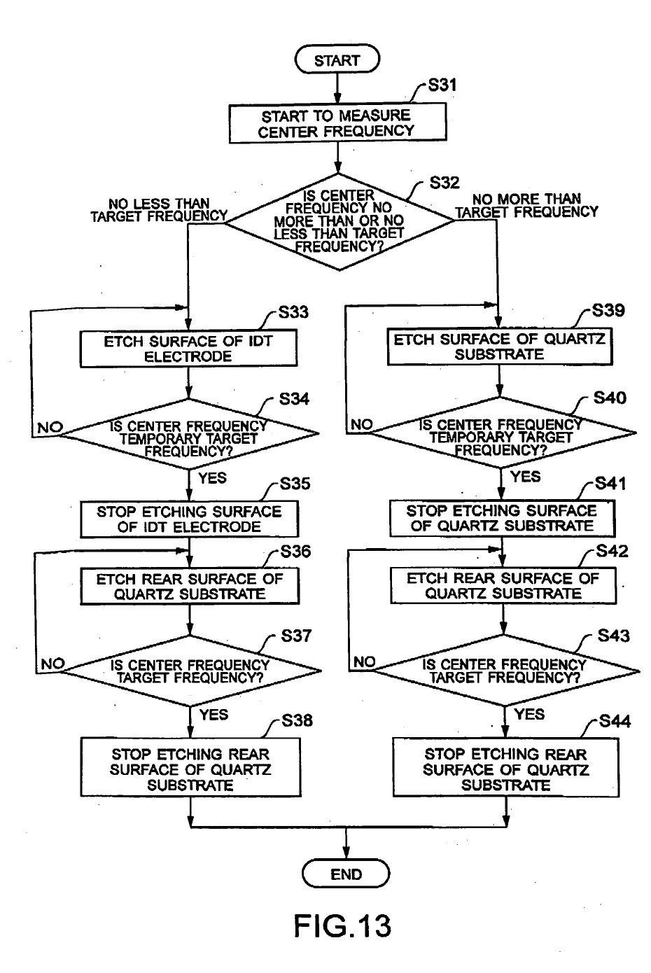

Also, since the frequency adjustment can be performed without invading the electrode pattern formed on the electrode-forming surface of the quartz substrate at all, a change of the center frequency is small with the lapse of time, and thus the surface acoustic wave device operating stably for a long-term can be realized. Next, the second method for the frequency adjustment of the surface acoustic wave device will be described with reference to FIG. 13.

This is a useful method in a case where a frequency adjustment is required due to variation in the thickness of the IDT electrode formed on the quartz substrate of the surface acoustic wave device. First, the measurement of the center frequency starts by applying a voltage to the IDT electrode 2 (step S31). Next, it is determined whether the measured center frequency is less than or more than the target value (step S32).

As a result of the determination, if the measured center frequency is less than the target value, step S33 is performed, and if the measured center frequency is more than the target value, step S39 is performed. Furthermore, if the measured center frequency is equal to the target value, the adjustment is finished since the frequency adjustment is unnecessary. In the step S33, the etching, for example, wet etching of the surface of the IDT electrode 2 is performed while confirming the measured frequency. Then, the measured center frequency rises in a short time by the etching. Then, the etching continues until the measured center frequency reaches ‘the temporary target value’ that is set to be slightly lower than the target value of the center frequency (steps S33 and S34), and the etching stops when the measured center frequency reaches ‘the temporary target value’ (step S35). In the following steps S33 and S34, the rough-adjustment (preliminary adjustment) of the frequency is performed.

Next, the etching of the rear surface 1b of the quartz substrate 1 is performed while confirming the measured frequency (step S36). Then, the measured center frequency rises gradually due to the etching and then approaches the target value. Then, the etching continues until the center frequency reaches the target value (steps S36 and S37), and then the etching stops when the measured center frequency reaches the target value (step S38). In the steps S36 and S37, the fine-adjustment of the frequency is performed.

On the other hand, in step S39, the etching (for example, wet etching) of the surface of the quartz substrate 1 is performed while confirming the measured frequency. Then, the measured center frequency decreases in a short time due to the etching. Then, the etching continues until the measured center frequency reaches ‘the temporary target value’ that is set to be slightly lower than the target value of the center frequency (steps S39 and S40), and then the etching stops when the measured center frequency reaches ‘the temporary target value’ (step S41). In the steps S39 and S40, the rough adjustment (preliminary adjustment) of the frequency is performed.

Next, the etching of the rear surface 1b of the quartz substrate 1 is performed while confirming the measured frequency (step S42). Then, the measured center frequency rises gradually due to the etching and approaches the target value. Then, the etching continues until the center frequency reaches the target value (steps S42 and S43), and then the etching stops when the center frequency reaches the target value (step S44). In the above steps S42 and S43, the fine adjustment of the frequency is performed.

According to the second embodiment of the method of adjusting the frequency, even in a case where the target value of the center frequency is unbalanced, the rough adjustment of the frequency is performed in a short time by the etching of the surface of the quartz substrate or the surface of the IDT electrode, and then the accurate frequency adjustment can be realized in a short time as a whole by performing the fine adjustment of the frequency by etching the rear surface of the quartz substrate. Also, since the rough adjustment of the frequency can be performed on the surface of the IDT electrode or the surface of the quartz substrate by wet etching and the fine adjustment can be performed on the rear surface of the quartz substrate by plasma etching, it is possible to prevent the frequency variation after adjustment due to the remaining aluminum that will cause a problem in a case where the surface of the quartz substrate is etched by plasma etching, and so on.

Also, in the above embodiment, although the rough adjustment of the frequency is performed by etching the surface of the quartz substrate (steps S39 and S40) or the surface of the IDT electrode (steps S33 and S34), and then the fine adjustment of the frequency is performed by etching the rear surface of the quartz substrate, the following adjustment method is available. In other words, as a result of the measurement of frequency in step S31, if the center frequency is less than the ‘first target value,’ the etching of the rear surface of the quartz substrate is immediately performed (step S36 or S32).

Furthermore, if necessary, the adjustment may be made such that the center frequency reaches the target value by etching the surface of the IDT electrode first, etching the surface of the quartz substrate, and etching the rear surface of the quartz substrate finally.

While this invention has been described in conjunction with specific embodiments above, it is evident that many alternatives, modifications and variations will be apparent to those skilled in the art. Accordingly, the preferred embodiments of the invention as set forth herein are intended to be illustrative, not limiting. Various changes may be made without departing from the spirit and scope of the invention.

What is claimed is:

1. A surface acoustic wave device having a quartz substrate and IDT electrodes arranged on the quartz substrate and exciting a quasi-longitudinal leaky surface acoustic wave,
a standardized substrate thickness t/λ, which standardizes a thickness t of the quartz substrate to an IDT wavelength λ, being set to be 1<t/λ<35.

2. The surface acoustic wave device according to claim 1, the quartz substrate being cut in a Euler angle range (0°, 100 to 150°, 0°).

3. The surface acoustic wave device according to claim 1, wherein in the quartz substrate, a reinforcing portion being provided on at least one of an IDT electrode-forming surface and a surface opposite thereto, the reinforcing portion being disposed in a region a in which the IDT electrodes are not formed.

4. An electronic apparatus including, as a filter or a resonator, the surface acoustic wave device according to claim 1.

5. A method of manufacturing a surface acoustic wave device, comprising:
adjusting a thickness of a quartz substrate;
forming IDT electrodes, which excite a quasi-longitudinal leaky surface acoustic wave, on the thickness-adjusted quartz substrate to obtain a surface acoustic wave element; and
fixing the surface acoustic wave element on a predetermined package;
wherein, in adjusting the thickness of the quartz substrate, the thickness of the quartz substrate is adjusted such that a standardized substrate thickness t/λ, which standardizes a thickness t of the quartz substrate to an IDT wave λ, satisfies 1<t/λ<35.

6. A method of manufacturing a surface acoustic wave device, comprising:
forming IDT electrodes, which excite a quasi-longitudinal leaky surface acoustic wave, on a quartz substrate to obtain a surface acoustic wave element;
adjusting a thickness of the quartz substrate by shaving a surface of the quartz substrate opposite to the IDT electrode-forming surface; and
fixing the surface acoustic wave element on a predetermined package;
wherein, in adjusting the thickness of the quartz substrate, the thickness of the quartz substrate is adjusted such that a standardized substrate thickness t/λ, which standardizes a thickness t of the quartz substrate to an IDT wave λ, satisfies 1<t/λ<35.

7. A method of manufacturing a surface acoustic wave device according to claim 5 the method further comprising a frequency-adjusting step of adjusting the frequency of the surface acoustic wave element after the third step,
the frequency being adjusted by adjusting the thickness of the quartz substrate at the surface opposite to the IDT electrode-forming surface.

8. A method of manufacturing a surface acoustic wave device according to claim 7, wherein, in the frequency-adjusting step, the surface of the quartz substrate opposite to the IDT electrode-forming surface is shaved by dry etching.

9. A method of manufacturing a surface acoustic wave device according to claim 7, the method further comprising a step of preliminarily adjusting the frequency by shaving at least one of the surface of the IDT electrodes and the IDT electrode-forming surface of the quartz substrate before the frequency-adjusting step.
